(19) United States
(12) Patent Application Publication
(10) Pub. No.: US 2022/0223426 A1
(43) Pub. Date: Jul. 14, 2022

(54) SEMICONDUCTOR STRUCTURE MANUFACTURING METHOD AND SEMICONDUCTOR STRUCTURE MANUFACTURING DEVICE

(71) Applicant: CHANGXIN MEMORY TECHNOLOGIES, INC., Hefei (CN)

(72) Inventor: Shih-Hung LEE, Hefei (CN)

(73) Assignee: CHANGXIN MEMORY TECHNOLOGIES, INC., Hefei (CN)

(21) Appl. No.: 17/453,850

(22) Filed: Nov. 7, 2021

Related U.S. Application Data
(63) Continuation of application No. PCT/CN2021/110077, filed on Aug. 2, 2021.

(30) Foreign Application Priority Data
Jan. 13, 2021 (CN) 202110043371.8

(51) Int. Cl. H01L 21/3065; H01J 37/305; H01J 37/20

(52) U.S. Cl. CPC H01L 21/3065; H01J 37/20; H01J 37/3053

(57) ABSTRACT

A semiconductor structure manufacturing method includes: providing a substrate; forming a patterned photoresist layer on the substrate, and etching the substrate by using the patterned photoresist layer as a mask; performing, by using a plasma asher, plasma ashing treatment on the patterned photoresist layer and residues produced by etching after the substrate is etched; and performing the plasma ashing treatment in an oxygen-free environment. According to the embodiments of the present application, residues on a semiconductor structure can be removed without producing new residues, thereby improving electrical properties of the semiconductor structure.

### CROSS-REFERENCE TO RELATED APPLICATIONS

This is a continuation of International Patent Application No. PCT/CN2021/110077 filed on Aug. 2, 2021, which claims priority to Chinese Patent Application No. 202110043371.8 filed on Jan. 13, 2021. The disclosures of the above-referenced applications are incorporated herein by reference in their entirety.

### BACKGROUND

Etching is a technology commonly used in a semiconductor structure manufacturing method. Etching is a main process of patterning associated with photolithography. Photoetching means first lithographically exposing a photoresist by photolithography and then corroding a to-be-removed portion by other means.

### SUMMARY

The present application relates to the field of semiconductors, and in particular, to a semiconductor structure manufacturing method and a semiconductor structure manufacturing device.

Various embodiments of the present application provide a semiconductor structure manufacturing method, including: providing a substrate; forming a patterned photoresist layer on the substrate, and etching the substrate by using the patterned photoresist layer as a mask; performing, by using a plasma asher, plasma ashing treatment on the patterned photoresist layer and residues produced by etching after the substrate is etched; and performing the plasma ashing treatment in an oxygen-free environment.

The embodiments of the present application further provide a semiconductor structure manufacturing device, adapted to perform plasma ashing treatment on residues on a semiconductor structure, the semiconductor structure including a substrate, the semiconductor structure manufacturing device including: a chuck and at least three support pillars; the chuck being configured to provide a heat source; the support pillar being located on the chuck, and the support pillar being configured to bear the substrate and detach the substrate from the chuck.

### BRIEF DESCRIPTION OF THE DRAWINGS

One or more embodiments are exemplarily described by using figures that are corresponding thereto in the accompanying drawings; the exemplary descriptions do not constitute limitations on the embodiments. Elements with same reference numerals in the accompanying drawings are similar elements. Unless otherwise particularly stated, the figures in the accompanying drawings do not constitute a scale limitation.

FIG. 1 is a first schematic structural diagram corresponding to steps in a semiconductor structure manufacturing method.

FIG. 2 is a second schematic structural diagram corresponding to steps in a semiconductor structure manufacturing method.

FIG. 3 is a third schematic structural diagram corresponding to steps in a semiconductor structure manufacturing method.

FIG. 4 is a first schematic structural diagram corresponding to steps in a semiconductor structure manufacturing method according to a first embodiment of the present application.

FIG. 5 is a second schematic structural diagram corresponding to steps in a semiconductor structure manufacturing method according to a first embodiment of the present application.

FIG. 6 is a third schematic structural diagram corresponding to steps in a semiconductor structure manufacturing method according to a first embodiment of the present application.

FIG. 7 is a schematic diagram of plasma ashing treatment according to the first embodiment of the present application.

FIG. 8 is a schematic structural diagram of a chuck and a support pillar according to the first embodiment of the present application.

### DETAILED DESCRIPTION

It can be known from the Background that, in a process of removing residues produced by etching, it is not easy to remove the residues thoroughly, and it is easy to produce new residues, thereby affecting the quality of a semiconductor structure.

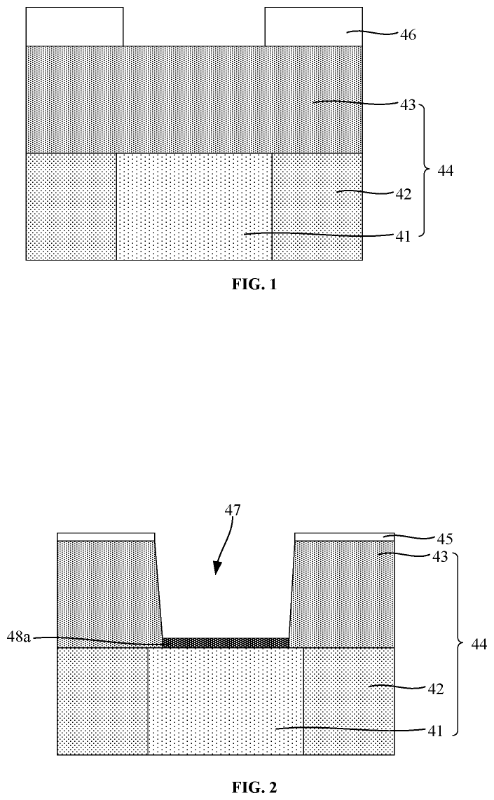

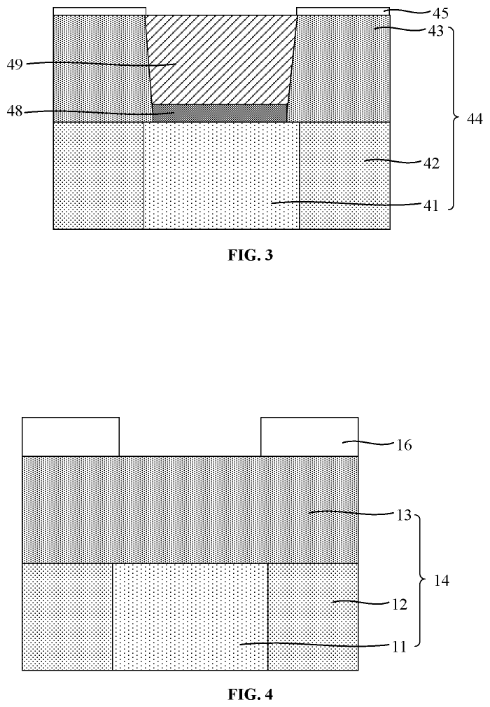

FIG. 1 to FIG. 3 are schematic structural diagrams corresponding to steps in a semiconductor structure manufacturing method. Specifically, referring to FIG. 1, a substrate 44 is provided. The substrate 44 includes first dielectric layers 42, a first metal layer 41 located between adjacent first dielectric layers 42, and a second dielectric layer 43 located on the first metal layer 41 and the first dielectric layer 42. A patterned photoresist layer 46 is formed on the second dielectric layer 43. Referring to FIG. 2, the second dielectric layer 43 is etched by using the patterned photoresist layer 46 (refer to FIG. 1) as a mask, so as to form a via 47 located in the second dielectric layer 43. During the etching, due to the influence of factors such as temperatures, etching reagents and chamber atmospheres, a first oxide layer 48a is easily produced on a surface of the first metal layer 41. Referring to FIG. 3, the patterned photoresist layer 46 is removed. During the removal of the patterned photoresist layer 46, an oxygen plasma ashing technology is generally used. Oxygen may further aggravate an oxidation reaction, and the first oxide layer 48a may not only not be thoroughly removed, but also be further thickened, thereby transforming into a second oxide layer 48. In addition, oxygen may also oxidize non-ashed residues in a photoresist, resulting in formation of an impurity layer 45 that is more difficult to remove. The impurity layer 45 may adversely affect the performance of the semiconductor structure. After the patterned photoresist layer 46 (refer to FIG. 1) is removed, a second metal layer 49 filling the via 47 (refer to FIG. 2) is formed. Since the second oxide layer 48 has a large resistance, this may lead to an increase in series resistance of the first metal layer 41 and the second metal layer 49. The increase in the resistance may lead to a slow operation rate and degradation of electrical properties of the semiconductor structure.

In order to solve the above problem, an embodiment of the present application provides a semiconductor structure manufacturing method, including: performing, by using a plasma asher, plasma ashing treatment on a patterned photoresist layer and residues produced by etching after a substrate is etched; and performing the plasma ashing treatment in an oxygen-free environment. In the oxygen-free environment, the plasma ashing treatment can not only remove an original oxide layer, but also prevent production of new residues, so as to ensure that the semiconductor structure has good electrical properties.

In order to make the objectives, technical solutions and advantages of the embodiments of the present application clearer, various embodiments of the present application will be described below in details with reference to the drawings. However, those of ordinary skill in the art may understand that, in the embodiments of the present application, numerous technical details are set forth in order to enable a reader to better understand the present application. However, the technical solutions claimed in the present application can be implemented without these technical details and various changes and modifications based on the embodiments below.

FIG. 4 to FIG. 8 illustrate a semiconductor structure manufacturing method according to one embodiment of the present application, which is specifically described below with reference to the accompanying drawings.

Referring to FIG. 4, a substrate 14 is provided. The substrate 14 may include an isolation layer and a conductive layer. The isolation layer is configured to isolate a plurality of conductive layers. In this embodiment, the substrate 14 includes a first metal layer 11, a first dielectric layer 12 and a second dielectric layer 13. The first metal layer 11 is located in the first dielectric layer 12. The second dielectric layer 13 is located on the first dielectric layer 12 and covers the first metal layer 11. The first dielectric layer 12 and the second dielectric layer 13 are isolation layers, for defining the first metal layer 11 and a subsequently-formed second metal layer.

In one embodiment, the first dielectric layer 12 is made of an insulation material such as silicon dioxide. In other embodiments, the first dielectric layer may also be made of silicon nitride, silicon carbonitride or silicon oxycarbide.

In one embodiment, the first metal layer 11 is made of a material with a lower resistivity, such as copper. In other embodiments, the first metal layer may also be made of tungsten, tantalum or titanium.

In one embodiment, the second dielectric layer 13 is made of an insulation material such as silicon dioxide. In other embodiments, the second dielectric layer may also be made of silicon nitride, silicon carbonitride or silicon oxycarbide.

A patterned photoresist layer 16 is formed on the substrate 14. For example, a photoresist layer is applied to the substrate 14, and the photoresist layer is exposed. The exposed photoresist layer may be treated with a solvent, so as to remove part of a photoresist to form the patterned photoresist layer 16.

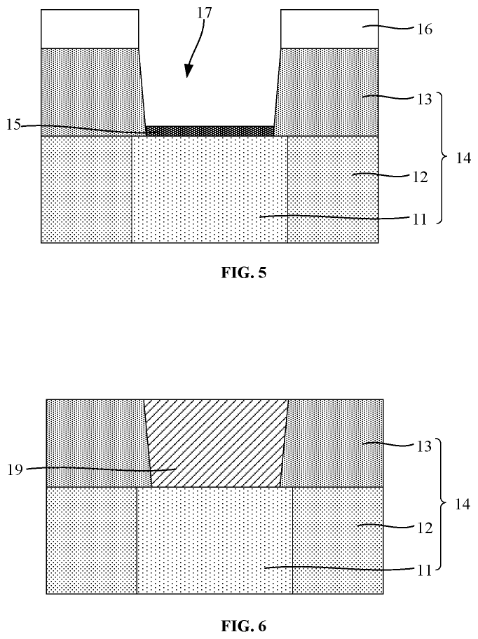

Referring to FIG. 5, the substrate 14 is etched by using the patterned photoresist layer 16 as a mask.

In this embodiment, the second dielectric layer 13 is etched by using the patterned photoresist layer 16 as a mask to form a via 17 located in the second dielectric layer 13, so as to expose the first metal layer 11.

In one embodiment, part of the second dielectric layer 13 is removed by dry etching. An etching gas may be carbon tetrafluoride, trifluoromethane or oxygen. Since the etching gas is oxidizing, residues such as an oxide layer 15 may be produced on the first metal layer 11. In other embodiments, part of the second dielectric layer may also be removed by wet etching.

Referring to FIG. 6 to FIG. 8, plasma ashing treatment is performed, by using a plasma asher, on the patterned photoresist layer 16 (refer to FIG. 5) and residues produced by etching. The plasma ashing treatment is performed in an oxygen-free environment.

The plasma ashing treatment in the oxygen-free environment can prevent further thickening of the oxide layer 15 (refer to FIG. 5), and can also remove the oxide layer 15 thoroughly, so as to ensure that the semiconductor structure has lower resistance. In addition, in the oxygen-free environment, substances in the photoresist that are difficult to ash may not be oxidized, and through a subsequent cleaning process, these substances that are difficult to ash may be removed thoroughly.

A reaction gas 23 is introduced during the plasma ashing treatment. The reaction gas 23 includes H₂N₂ or NH₃. H₂N₂ or NH₃ having certain reducibility, which can further remove residual oxides on the first metal layer 11 and can also prevent production of new oxides on the first metal layer 11. In addition, H₂N₂ or NH₃ is less corrosive and may not cause great damages to the first dielectric layer 12 and the second dielectric layer 13.

In one embodiment, a flow rate of H₂N₂ is 3000 sccm to 10000 sccm, which may be, for example, 4000 sccm, 5000 sccm or 8000 sccm. When the flow rate of H₂N₂ is in the above range, process time can be shortened to some extent and damages to the semiconductor structure can also be prevented.

In yet another embodiment, a flow rate of NH₃ is 1000 sccm to 10000 sccm, which may be, for example, 2000 sccm, 4000 sccm or 7000 sccm. When the flow rate of NH₃ is in the above range, process time can be shortened to some extent and damages to the semiconductor structure can also be prevented.

In one embodiment, the reaction gas 23 further includes nitrogen during the plasma ashing treatment. Nitrogen, as an inactive gas, can improve hardness and wear resistance of the semiconductor structure to some extent. In addition, plasma produced by nitrogen has a strong bombardment on a surface of the semiconductor structure, so nitrogen can also improve an ashing effect, so as to increase cleanliness of the semiconductor structure.

During the plasma ashing treatment, a chamber temperature is lower and is in a range of 50° C. to 250° C., which can be, for example, 100° C., 110° C., 120° C., 150° C. or 200° C. It may be understood that if the chamber temperature is higher, oxygen atoms in the oxide layer 15 (refer to FIG. 5) are highly reactive. The oxygen atoms in the oxide layer 15 may diffuse towards the first metal layer 11 before the oxide layer 15 is completely ashed. If a content of the oxygen atoms in the first metal layer 11 is increased, resistance of the first metal layer 11 may be increased, thereby reducing an operation rate of the semiconductor structure. If the chamber temperature is too low, the time of the plasma ash treatment may be increased. When the chamber temperature is in the above range, the probability of diffusion of the oxygen atoms in the oxide layer 15 can be reduced, and the time of the plasma ash treatment can also be kept in a reasonable range.

In one embodiment, a chamber pressure is in a range of 50 mtorr to 2000 mtorr during the plasma ashing treatment, which may be, for example, 100 mtorr, 500 mtorr or 1000 mtorr. When the chamber pressure is in the above range, the efficiency of ashing treatment can be improved. The lower the pressure is, the less a metal surface is oxidized.

In one embodiment, radio frequency power is 1000 W to 5000 W during the plasma ashing treatment, which may be, for example, 2000 W, 3000 W or 4000 W. When the radio frequency power is in the above range, energy of the plasma can be increased, so as to increase degrees of ashing of the photoresist and the oxide.

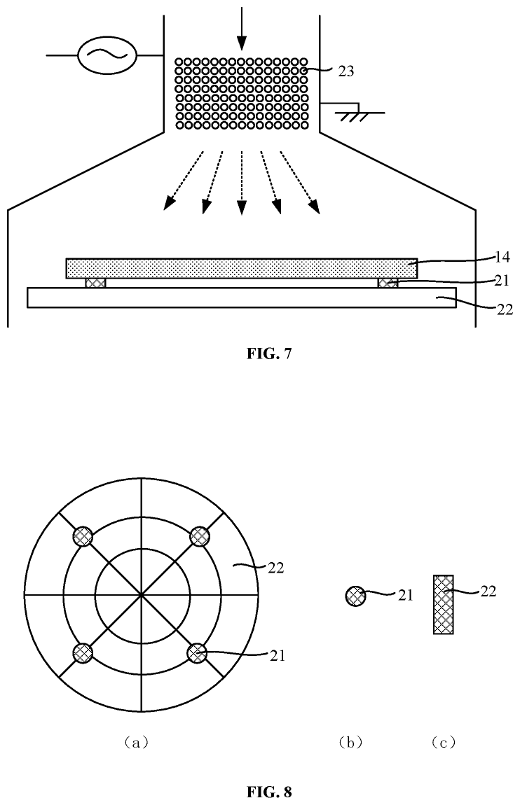

FIG. 7 is a schematic diagram of plasma ashing treatment, FIG. 8 is a schematic structural diagram of a chuck and a support pillar, FIG. 8(a) is a top view of the chuck and the support pillar, FIG. 8(b) is a top view of the support pillar, and FIG. 8(c) is a front view of the support pillar. Referring to FIG. 7 and FIG. 8, the plasma asher includes a chuck 22 and at least three support pillars 21. The chuck 22 is configured to provide a heat source. The support pillar 21 is configured to bear the substrate 14 and detach the substrate 14 from the chuck 22.

That is, the support pillar 21 lifts the substrate 14, which can prevent direct contact between the substrate 14 and the chuck 22, so as to reduce a heating rate of the substrate 14. A lower temperature rise speed can reduce a degree of diffusion of the oxygen atoms in the oxide layer 15 (refer to FIG. 5), so as to prevent great influence on the conductivity of the first metal layer 11 (refer to FIG. 5).

In one embodiment, the support pillar is configured to bear the substrate and detach the substrate from the chuck. That is, the support pillar can prevent direct contact between the chuck and the substrate, so as to reduce a temperature rise rate of the substrate, reduce oxidation capacity of a surface of a metal layer, prevent formation of an additional oxide layer to resist electrical conductivity of metal, and reduce a degree of diffusion of oxygen atoms in the oxide layer towards a first metal layer, so that the semiconductor structure has good electrical properties.

In the process of providing the heat source by the chuck 22, a temperature variation process of the substrate 14 includes a temperature rise stage and a constant temperature stage. It is to be noted that, in the temperature rise stage, the oxide layer 15 (refer to FIG. 5) and the patterned photoresist layer 16 (refer to FIG. 5) may be ashed at the same time, and at the end of the temperature rise stage, most of the oxide layer 15 is removed. In the constant temperature stage, the remaining patterned photoresist layer 16 is mainly ashed.

Main reasons for controlling a removal process of the oxide layer 15 (refer to FIG. 5) and the patterned photoresist layer 16 (refer to FIG. 5) in stages are as follows. At a lower temperature, the oxygen atoms in the oxide layer 15 diffuse slowly, which has little effect on the resistance of the first metal layer 11. In the temperature rise stage, the substrate 14 is at a lower temperature; therefore, removal of most of the oxide layer 15 in this stage can prevent violent diffusion of the oxygen atoms in the subsequent constant temperature stage. In the constant temperature stage, the substrate 14 is at a higher temperature, which can speed up the removal of the patterned photoresist layer 16, thereby shortening the process time.

A height of the support pillar 21 in the temperature rise stage is greater than that in the constant temperature stage. It may be understood that if the height of the support pillar 21 is higher in the temperature rise stage, heat received by the substrate 14 may be reduced, and then the probability of diffusion of the oxygen atoms is reduced; if the height of the support pillar 21 is lower in the constant temperature stage, the heat received by the substrate 14 may be increased, so as to ensure that the substrate 14 has a higher temperature to speed up the ashing process of the patterned photoresist layer 16, improve the efficiency and reduce costs.

In one embodiment, in the temperature rise stage, the height of the support pillar 21 decreases gradually in a direction perpendicular to an upper surface of the chuck 22. In the constant temperature stage, the height of the support pillar 21 remains constant in the direction perpendicular to the upper surface of the chuck 22. Main reasons are as follows. At the beginning of the temperature rise stage, that is, when the chuck 22 just starts to provide the heat source, a degree of temperature variation of the substrate 14 is great; with the continuous heating of the chuck 22, the degree of temperature variation of the substrate 14 decreases gradually. At the beginning of the temperature rise stage, the support pillar 21 has a higher height, which can decrease the degree of temperature variation of the substrate 14. With the constant rise of the temperature, the height of the support pillar 21 decreases gradually, which can ensure that the substrate 14 can reach a preset temperature quickly, thereby shortening the time of plasma ashing treatment of the photoresist.

In the temperature rise stage, a temperature rise rate of the substrate 14 is 5° C./s to 20° C./s, which may specifically be 8° C./s, 12° C./s or 18° C./s. When the temperature rise rate is in the above range, the degree of diffusion of the oxygen atoms can be reduced, and the oxide layer 15 can be ensured to be more thoroughly removed.

In addition, the height of the support pillar 21 in the direction perpendicular to the upper surface of the chuck 22 may be 3 mm to 20 mm, which may specifically be 8 mm, 12 mm or 18 mm. When the height of the support pillar 21 is in the above range, it can be ensured that the substrate 14 can have a more appropriate heating rate, so that a diffusion rate of the oxygen atoms in the oxide layer 15 can be reduced, and the time of the plasma ashing treatment can also be reasonably controlled.

In other embodiments, the height of the support pillar may also remain unchanged.

In one embodiment, four support pillars 21 are provided. The four support pillars 21 can improve stability of placement of the substrate 14. In other embodiments, three or four or more support pillars may also be provided.

In one embodiment, the plurality of support pillars 21 may be equidistant from a central axis of the chuck 22. In this way, after the substrate 14 is placed on the support pillar 21, the substrate 14 can be subjected to a more uniform force, thereby improving the stability of the substrate 14.

In one embodiment, the support pillar 21 may consist of a plurality of sleeve rods nested in sequence. When the sleeve rod extends, the height of the support pillar 21 is increased. When the sleeve contracts, the height of the support pillar 21 is reduced. In other embodiments, a push rod may also be arranged inside the support pillar, and expansion of the push rod can control the rise or fall of the support pillar.

In one embodiment, the support pillar 21 is made of ceramic. Due to low thermal conductivity of the ceramic, rapid transfer of heat by the chuck 22 to the substrate 14 through the support pillar 21 can be prevented. In this way, the temperature rise rate of the substrate 14 can be reduced to reduce the diffusion rate of the oxygen atoms, thereby preventing an increase in the resistance of the first metal layer 11. In other embodiments, the support pillar may also be made of metals with low thermal conductivity.

Referring to FIG. 6, SO₃ gas is introduced to treat the substrate 14 after the plasma ashing treatment. The SO₃ gas has strong oxidation and can further remove impurities such as organic matters.

The SO₃ gas is anhydrous, and during the introduction, the chamber temperature is lower. It is difficult for the anhydrous SO₃ gas at a low temperature to oxidize the first metal layer 11. Therefore, no new oxide impurities may be produced during the above treatment, nor may the electrical properties of the first metal layer 11 be adversely affected.

The semiconductor structure is cleaned using a mixed solution of dilute sulfuric-peroxide-HF (DSP) and a dilute HF (DHF) solution. The above solution can further remove impurities such as oxides and inorganic matters.

In the DSP solution, H₂O₂ has a mass concentration of 1 wt % to 5 wt %; H₂SO₄ has a mass concentration of 1 wt % to 10 wt %; and HF has a mass concentration of 0.01 wt % to 0.08 wt %. When the concentration of each component is in the above range, the impurities can be thoroughly removed, and damages to the semiconductor structure can also be prevented.

In the DHF solution, HF: H₂O=1:100 to 1:2000. When the concentration of each component is in the above range, cleanliness of the semiconductor structure can be improved, and damages to the semiconductor structure can also be prevented.

It is to be noted that, since Ammonia Peroxide Mix (APM) is not used in this embodiment, the first metal layer 11 and a second metal layer 19 may not be damaged.

The second metal layer 19 is formed on the first metal layer 11. The second metal layer 19 further fills the via 17 (refer to FIG. 5).

Since the oxide layer 15 on the surface of the first metal layer 11 is more thoroughly removed, the first metal layer 11 and the second metal layer 19 have low series resistance, and the semiconductor structure has better electrical properties.

The first metal layer 11 is made of low resistance metals such as copper, tungsten, titanium, gold, tantalum or silver, so that the resistance of the semiconductor structure can be reduced and operating efficiency of the semiconductor structure can be improved.

Based on the above, in this embodiment, the patterned photoresist layer 16 and impurities such as the residual oxide layer 15 are ashed in the oxygen-free environment, which enables the oxide layer 15 to be more thoroughly removed without producing new residues. In addition, the support pillar 21 is used to lift the substrate 14, which can avoid the direct contact between the chuck 22 and the substrate 14, so as to reduce the temperature rise rate of the substrate 14 and prevent an affection of the electrical properties of the semiconductor structure caused by diffusion of the oxygen atoms in the oxide layer 15 into the first metal layer 11.

Another embodiment of the present application provides a semiconductor structure manufacturing device. The semiconductor structure manufacturing device is adapted to perform plasma ashing treatment on residues on a semiconductor structure. FIG. 7 to FIG. 8 are schematic diagrams according to this embodiment. Referring to FIG. 7 to FIG. 8, the semiconductor structure includes a substrate 14. The semiconductor structure manufacturing device includes: a chuck 22 and at least three support pillars 21. The chuck 22 is configured to provide a heat source. The support pillar 21 is configured to bear the substrate 14 and detach the substrate 14 from the chuck 22.

Contents in this embodiment the same as or similar to those in the first embodiment can be obtained with reference to the first embodiment, which are not described in detail herein.

Referring to FIG. 7 to FIG. 8, the support pillar 21 lifts the substrate 14, which can prevent direct contact between the substrate 14 and the chuck 22, so as to reduce a heating rate of the substrate 14. A lower temperature rise speed can reduce a degree of diffusion of oxygen atoms in the oxide layer 15 (refer to FIG. 5), so as to prevent great influence on the conductivity of the first metal layer 11 (refer to FIG. 5).

In one embodiment, in the process of providing the heat source by the chuck 22, a temperature variation process of the substrate 14 includes a temperature rise stage and a constant temperature stage. It is to be noted that, in the temperature rise stage, the oxide layer 15 and the patterned photoresist layer 16 (refer to FIG. 5) may be ashed at the same time, and at the end of the temperature rise stage, the oxide layer 15 may be more thoroughly removed. In the constant temperature stage, the remaining patterned photoresist layer 16 is mainly ashed.

Main reasons for controlling a removal process of the oxide layer 15 and the patterned photoresist layer 16 in stages are as follows. At a lower temperature, the oxygen atoms in the oxide layer 15 diffuse slowly, which has little effect on the resistance of the first metal layer 11. In the temperature rise stage, the substrate 14 is at a lower temperature; therefore, complete removal of the oxide layer 15 in this stage can prevent violent diffusion of oxygen atoms in the subsequent constant temperature stage. In the constant temperature stage, the substrate 14 is at a higher temperature, which can speed up the removal of the patterned photoresist layer 16, thereby shortening the process time.

A height of the support pillar 21 in the temperature rise stage is greater than that in the constant temperature stage. It may be understood that if the height of the support pillar 21 is higher in the temperature rise stage, heat received by the substrate 14 may be reduced, and then the probability of diffusion of the oxygen atoms is reduced; if the height of the support pillar 21 is lower in the constant temperature stage, the heat received by the substrate 14 may be increased, so as to ensure that the substrate 14 has a higher temperature to speed up the ashing process of the patterned photoresist layer 16.

In one embodiment, in the temperature rise stage, the height of the support pillar 21 decreases gradually in a direction perpendicular to an upper surface of the chuck 22. In the constant temperature stage, the height of the support pillar 21 remains constant in the direction perpendicular to the upper surface of the chuck 22. Main reasons are as follows. At the beginning of the temperature rise stage, that is, when the chuck 22 just starts to provide the heat source, a degree of temperature variation of the substrate 14 is great; with the continuous heating of the chuck 22, the degree of temperature variation of the substrate 14 decreases gradually. At the beginning of the temperature rise stage, the support pillar 21 has a higher height, which can decrease the degree of temperature variation of the substrate 14. With the constant rise of the temperature, the height of the support pillar 21 decreases gradually, which can ensure that the substrate 14 can reach a preset temperature quickly, thereby shortening the time of plasma ashing treatment of the photoresist.

A temperature rise rate of the substrate 14 is 5° C./s to 20° C./s in the temperature rise stage. When the temperature rise rate is in the above range, a degree of diffusion of the oxygen atoms can be reduced, and the oxide layer 15 can be ensured to be more thoroughly removed.

In addition, the height of the support pillar 21 in the direction perpendicular to the upper surface of the chuck 22 may be 3 mm to 20 mm. When the height of the support pillar 21 is in the above range, it can be ensured that the substrate 14 can have a more appropriate heating rate, so that a diffusion rate of the oxygen atoms in the oxide layer 15 can be reduced, and the time of the plasma ashing treatment can also be reasonably controlled.

In yet other embodiment, the height of the support pillar may also remain unchanged.

In one embodiment, four support pillars 21 are provided. The four support pillars 21 can improve stability of placement of the substrate 14. In other embodiments, three or four or more support pillars may also be provided.

In addition, the plurality of support pillars 21 may be equidistant from a central axis of the chuck 22. In this way, after the substrate 14 is placed on the support pillar 21, the substrate 14 can be subjected to a more uniform force, thereby improving the stability of the substrate 14.

In one embodiment, the support pillar 21 may consist of a plurality of sleeve rods nested in sequence. When the sleeve rod extends, the height of the support pillar 21 is increased. When the sleeve contracts, the height of the support pillar 21 is reduced. In other embodiments, a push rod may also be arranged inside the support pillar, and expansion of the push rod can control the rise or fall of the support pillar.

In one embodiment, the support pillar 21 is made of ceramic. Due to low thermal conductivity of the ceramic, rapid transfer of heat by the chuck 22 to the substrate 14 through the support pillar 21 can be prevented. In this way, the temperature rise rate of the substrate 14 can be reduced to reduce the diffusion rate of the oxygen atoms, thereby preventing an increase in the resistance of the first metal layer 11. In other embodiments, the support pillar may also be made of metals with low thermal conductivity.

Based on the above, the semiconductor structure manufacturing device according to this embodiment includes a chuck 22 and a plurality of support pillars 21 located on the chuck 22. The plurality of support pillars 21 may support the substrate 14 to prevent direct contact between the substrate 14 and the chuck 22, so as to reduce a heating degree of the substrate 14 and reduce a degree of diffusion of impurity atoms such as oxygen atoms on the substrate 14, thereby ensuring good electrical properties of the semiconductor structure.

Those of ordinary skill in the art may understand that the above implementations are specific embodiments for implementing the present application. However, in practical applications, various changes in forms and details may be made thereto without departing from the spirit and scope of the present application. Any person skilled in the art can make respective changes and modifications without departing from the spirit and scope of the present application. Therefore, the protection scope of the present application should be subject to the scope defined by the claims.

What is claimed is:

1. A semiconductor structure manufacturing method, comprising:
providing a substrate;
forming a patterned photoresist layer on the substrate, and etching the substrate by using the patterned photoresist layer as a mask;
performing, by using a plasma asher, plasma ashing treatment on the patterned photoresist layer and residues produced by etching after the substrate is etched; and
performing the plasma ashing treatment in an oxygen-free environment.

2. The semiconductor structure manufacturing method according to claim 1, wherein the plasma asher comprises a chuck and at least three support pillars; the chuck is configured to provide a heat source; the support pillar is located on the chuck, and the support pillar is configured to bear the substrate and detach the substrate from the chuck.

3. The semiconductor structure manufacturing method according to claim 2, wherein a reaction gas is introduced during the plasma ashing treatment, the reaction gas comprising H₂N₂ or NH₃.

4. The semiconductor structure manufacturing method according to claim 3, wherein a flow rate of H₂N₂ is 3000 sccm to 10000 sccm; and a flow rate of NH₃ is 1000 sccm to 10000 sccm.

5. The semiconductor structure manufacturing method according to claim 3, wherein the reaction gas further comprises N₂.

6. The semiconductor structure manufacturing method according to claim 2, wherein a chamber temperature is in a range of 50° to 250° during the plasma ashing treatment.

7. The semiconductor structure manufacturing method according to claim 2, wherein a chamber pressure is in a range of 50 mtorr to 2000 mtorr during the plasma ashing treatment.

8. The semiconductor structure manufacturing method according to claim 2, wherein in the process of providing the heat source by the chuck, a temperature variation process of the substrate comprises a temperature rise stage and a constant temperature stage; in the temperature rise stage, a height of the support pillar decreases gradually in a direction perpendicular to an upper surface of the chuck; in the constant temperature stage, the height of the support pillar remains constant in the direction perpendicular to the upper surface of the chuck; and the height of the support pillar in the temperature rise stage is greater than that in the constant temperature stage.

9. The semiconductor structure manufacturing method according to claim 8, wherein a temperature rise rate of the substrate is 5° C./s to 20° C./s in the temperature rise stage.

10. The semiconductor structure manufacturing method according to claim 2, wherein the height of the support pillar in the direction perpendicular to the upper surface of the chuck is 3 mm to 20 mm.

11. The semiconductor structure manufacturing method according to claim 2, wherein the plurality of support pillars are equidistant from a central axis of the chuck.

12. The semiconductor structure manufacturing method according to claim 2, wherein a material of the support pillar comprises ceramic.

13. The semiconductor structure manufacturing method according to claim 2, wherein SO₃ gas is introduced to treat the substrate after the plasma ashing treatment.

14. The semiconductor structure manufacturing method according to claim 2, wherein the substrate comprises a first metal layer, a first dielectric layer and a second dielectric layer, and the first metal layer is located in the first dielectric layer; the second dielectric layer is located on the first dielectric layer and covers the first metal layer; the step of etching the substrate by using the patterned photoresist layer as a mask comprises: etching the second dielectric layer by using the patterned photoresist layer as a mask to expose the first metal layer; and after the plasma ashing treatment, the method further comprises: forming a second metal layer on the first metal layer.

15. A semiconductor structure manufacturing device, adapted to perform plasma ashing treatment on residues on a semiconductor structure, the semiconductor structure comprising a substrate, the semiconductor structure manufacturing device comprising: a chuck and at least three support pillars; the chuck being configured to provide a heat source; the support pillar being located on the chuck, and the support pillar being configured to bear the substrate and detach the substrate from the chuck.
